(19) United States
(12) Patent Application Publication
(10) Pub. No.: US 2019/0035445 A1
(43) Pub. Date: Jan. 31, 2019

(54) Method and Apparatus for Providing Low Latency Solid State Memory Access

(71) Applicant: Yiren Ronnie Huang, San Jose, CA (US)

(72) Inventor: Yiren Ronnie Huang, San Jose, CA (US)

(73) Assignee: CNEX Labs, Inc. a Delaware Corporation, San Jose, CA (US)

(21) Appl. No.: 15/665,068

(22) Filed: Jul. 31, 2017

(51) Int. Cl. G11C 8/18; G06F 12/123; G06F 12/0862

(52) U.S. Cl. CPC G11C 8/18; G06F 12/0862; G06F 12/123

(57) ABSTRACT

One embodiment of the present invention discloses a process of low latency non-volatile memory access using various approaches. In one aspect, a process for low latency memory access to a non-volatile memory (“NVM”) of a solid state drive (“SSD”) is able to generate a submission queue entry (“SQE”) for an SSD memory access by a host to a connected SSD. Upon pushing the SQE from the host to a submission queue (“SQ”) viewable by a controller of the SSD, the counter value of an SQ header pointer is incremented to reflect storage of the first SQE in the SQ. After detecting the SQE in the SQ by a snooping component in the memory controller in accordance with the SQ header pointer, the SQE is fetched from the SQ by the controller and one or more SSD memory instructions are subsequently executed in response to content of the SQE.

### FIELD

The exemplary embodiment(s) of the present invention relates to the field of semiconductor and integrated circuits. More specifically, the exemplary embodiment(s) of the present invention relates to non-volatile memory (“NVM”) storage devices.

### BACKGROUND

With increasing popularity of electronic devices, such as computers, smart phones, mobile devices, automobiles, drones, real-time images, wireless devices, server farms, mainframe computers, and the like, the demand for reliable data storage with high-speed is constantly growing. To handle voluminous data between various electronic devices, high-volume non-volatile memory (“NVM”) storage devices are in high demand. A conventional NVM storage device, for example, is flash based storage device typically known as solid-state drive (“SSD”).

The flash memory based SSD, for example, is an electronic NV storage device using arrays of flash memory cells. The flash memory can be fabricated with several different types of integrated circuit (“IC”) technologies such as NOR or NAND logic gates with, for example, floating-gate transistors. Depending on the applications, a typical flash memory based NVM is organized in blocks wherein each block is further divided into pages. The access unit for a typical flash based NVM storage is a page while conventional erasing unit is a block at a given time.

A problem, however, associated with a conventional NVM SSD is that the interface between a host system and an SSD can consume time and resource. For example, after a host system stores an entry in a submission queue and activates a doorbell process for notification, the SSD controller issues a direct memory access (“DMA”) to obtain SQE command entry. Another drawback associated with the process of doorbell is that it consumes time and resource which can degrade overall performance of the SSD. Another problem associated with a conventional NVM SSD is relating to programming impediment or block which impedes, for example, read operations during a write or erase operation.

### SUMMARY

One embodiment of the present invention discloses a process of low latency access to non-volatile memory (“NVM”) in SSD access using various approaches. In one aspect, a memory controller snooping (“MCS”) process for low latency memory access to NVM SSD is able to generate a submission queue entry (“SQE”) for an SSD memory access by a host to a connected SSD. Upon pushing the SQE from the host to a submission queue (“SQ”) which is viewable by a SSD controller, the counter value of SQ header pointer is incremented to reflect the storage of newly arrived SQE in SQ. After detecting the SQE by a snooping component of SSD controller in accordance with the SQ header pointer, the SQE is fetched from SQ by SSD controller and one or more SSD memory instructions are subsequently executed in response to content of the SQE.

In another embodiment, a host CPU polling (“HCP”) process for low latency memory access to an NVM of SSD is capable of simplifying host and SSD interface by polling the completion queue (“CQ”) based on an earlier SQE. After generating a completion queue entry (“CQE”) in accordance with the performance of the SQE, the SSD controller stores or deposits the CQE to CQ which is viewable by the host. Upon periodically CQ polling conducted by the host, the CQE is fetched from CQ upon detection via the polling activity. The host subsequently obtains the result of the performance based on the CQE.

To provide a low latency memory access, a process of cache content accessing (“CCA”) is employed. CCA, in one embodiment, confines the programming activate to one LUN at a given time whereby the programming block or impediment to read operation is optimized. For example, after receiving a write command, the SSD controller limits or confines writing process associated with the write command to one (1) logic unit (“LUN”) at a given time. Upon caching the content associated with write command to a cache while the content is written to the LUN, the host is allowed to access the content via the cache while the LUN is being programmed in accordance with the write command. In addition, the writing or programming to LUN can also occur due to the process of garbage collection.

To support consistent low latency memory access to SSD, a process of LUN block erasing (“LBE”) is employed to ascertain renewal of LUN before reprogramming. In one embodiment, LBE process receives a write command by a memory controller from a host for an SSD memory access. After identifying a targeted LUN in SSD as a destination storage location for the write command, all valid pages of blocks in targeted LUN are moved to new block on new LUN and the old blocks in the targeted LUN are subsequently erased. Upon completion of the erasing process, the content of write command is programmed or written to the targeted LUN.

By programming one LUN at a time, the program blocking of SQE IO read command can be reduced if the reading is directed to other LUNs. Furthermore, if we cache the data entry of the host write to the LUN is cached while the data entry is being programmed by SSD FW (firmware) CPU, the program blocking can be further minimized for host IO write data to a new LUN.

To further optimize latency of memory access, a command of memory access to a busy LUN can be temporarily buffered or parked for reducing traffic congestion. For example, at a time SQE entry is processed by FW embedded CPU, the NAND flash memory LUN status can be inspected. If the destined or targeted LUN is busy for the SQE command write or read operation, the SQE command can be stored temporarily in a buffer space to avoid head of line blocking. When LUN becomes non-busy, embedded CPU can later retrieve the stored SQE command from the buffer space or parking lot. The retrieved SQE command is subsequently processed.

Additional features and benefits of the exemplary embodiment(s) of the present invention will become apparent from the detailed description, figures and claims set forth below.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIGS. 1A-1B are a block diagrams illustrating a host system able to access NVM in an SSD with low latency access time in accordance with one embodiment of the present invention;

FIG. 2 is a block diagram illustrating a low latency component containing memory controller snooping (“MCS”), host CPU polling (“HCP”), cache content accessing (“CCA”), LUN block erasing (“LBE”), and/or submission queue entry (“SQE”) temporarily parking (“STP”) components capable of providing low latency memory access in accordance with one embodiment of the present invention;

FIG. 3 is a block diagram illustrating a host and SSD capable of providing low latency memory access using a memory controller snooping (“MCS”) approach in accordance with one embodiment of the present invention;

FIG. 4 is a block diagram illustrating a host and SSD capable of providing low latency memory access using a host CPU polling (“HCP”) approach in accordance with one embodiment of the present invention;

FIGS. 5A-B are block diagrams illustrating a host and SSD capable of providing low latency memory access using a cache content accessing (“CCA”) and/or access erase-marked LUN (“AEL”) approach in accordance with one embodiment of the present invention;

FIG. 6A is a block diagram illustrating a host and SSD capable of providing low latency memory access using a LUN block erasing (“LBE”) approach in accordance with one embodiment of the present invention;

FIG. 6B is a block diagram illustrating a host and SSD capable of providing low latency memory access using a SQE temporarily parking (“STP”) approach in accordance with one embodiment of the present invention;

FIG. 7 is a block diagram illustrating a host or memory controller capable of providing low latency memory access in accordance with one embodiment of the present invention;

FIG. 8 is a flowchart illustrating a process of providing low latency memory access using the MCS approach in accordance with one embodiment of the present invention;

FIG. 9 is a flowchart illustrating a process of providing low latency memory access using the HCP approach in accordance with one embodiment of the present invention;

FIG. 10 is a flowchart illustrating a process of providing low latency memory access using the CCA approach in accordance with one embodiment of the present invention;

FIG. 11 is a flowchart illustrating a process of providing low latency memory access using the LBE approach in accordance with one embodiment of the present invention;

FIG. 12 is a flowchart illustrating a process of providing low latency memory access using an access erase-marked LUN (“AEL”) approach in accordance with one embodiment of the present invention; and

FIG. 13 is a flowchart illustrating a process of providing low latency memory access using SQE temporarily parking (“STP”) approach in accordance with one embodiment of the present invention.

### DETAILED DESCRIPTION

Embodiments of the present invention are described herein with context of a method and/or apparatus for providing a low latency memory access to non-volatile memory (“NVM”) in a solid state drive (“SSD”).

The purpose of the following detailed description is to provide an understanding of one or more embodiments of the present invention. Those of ordinary skills in the art will realize that the following detailed description is illustrative only and is not intended to be in any way limiting. Other embodiments will readily suggest themselves to such skilled persons having the benefit of this disclosure and/or description.

In the interest of clarity, not all of the routine features of the implementations described herein are shown and described. It will, of course, be understood that in the development of any such actual implementation, numerous implementation-specific decisions may be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of embodiment(s) of this disclosure.

Various embodiments of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method. The same reference indicators will be used throughout the drawings and the following detailed description to refer to the same or like parts.

In accordance with the embodiment(s) of present invention, the components, process steps, and/or data structures described herein may be implemented using various types of operating systems, computing platforms, computer programs, and/or general purpose machines. In addition, those of ordinary skills in the art will recognize that devices of a less general purpose nature, such as hardware devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

The term “system” or “device” is used generically herein to describe any number of components, elements, sub-systems, devices, packet switch elements, packet switches, access switches, routers, networks, computer and/or communication devices or mechanisms, or combinations of components thereof. The term “computer” includes a processor, memory, and buses capable of executing instruction wherein the computer refers to one or a cluster of computers, personal computers, workstations, mainframes, or combinations of computers thereof.

One embodiment of the present invention discloses a process of low latency NVM access using MCS, HCP, CCA, LBE, or a combination of MCS, HCP, CCA, and/or LBE operations. In one aspect, a MCS process for low latency memory access to NVM SSD is able to generate a SQE for an SSD memory access by a host to a connected SSD. Upon pushing the SQE from the host to a SQ which is viewable by a SSD controller, the counter value of SQ header pointer is incremented to reflect the storage of newly arrived SQE in SQ. After detecting the SQE write by a snooping component of SSD controller in accordance with the SQ header pointer, the SQE is cached by the SSD controller that later can be executed in response to content of the SQE.

In another embodiment, a HCP process for low latency memory access to an NVM of SSD is capable of simplifying host and SSD interface by polling CQ based on an earlier SQE. After generating a CQE in accordance with the performance of the SQE, the SSD controller stores or deposits the CQE to CQ which is viewable by the host. Upon periodically CQ polling conducted by the host, the CQE is fetched from CQ upon detection via the polling activity. The host subsequently obtains the result of the performance based on the CQE.

To provide a low latency memory access, a process of CCA is employed. CCA, in one embodiment, confines the programming action to one LUN at a given time whereby the programming block or impediment to read operation is optimized. For example, after receiving a write command, the SSD controller limits or confines writing process associated with the write command to one (1) LUN at a given time. Upon caching the content associated with write command to a cache while the content is written to the LUN, the host is allowed to access the content via the cache while the LUN is being programmed in accordance with the write command. In addition, the writing or programming to LUN can also occur due to the process of garbage collection.

To support low latency memory access to SSD, a process of LBE is employed to ascertain renewal of LUN before reprogramming. In one embodiment, LBE process receives a write command by a memory controller from a host for an SSD memory access. After identifying a targeted LUN in SSD as a destination storage location for the write command, all valid blocks or pages in targeted LUN are removed and old blocks in targeted LUN are erased. Upon completion of the erasing process, the content of write command is programmed or written to the targeted LUN.

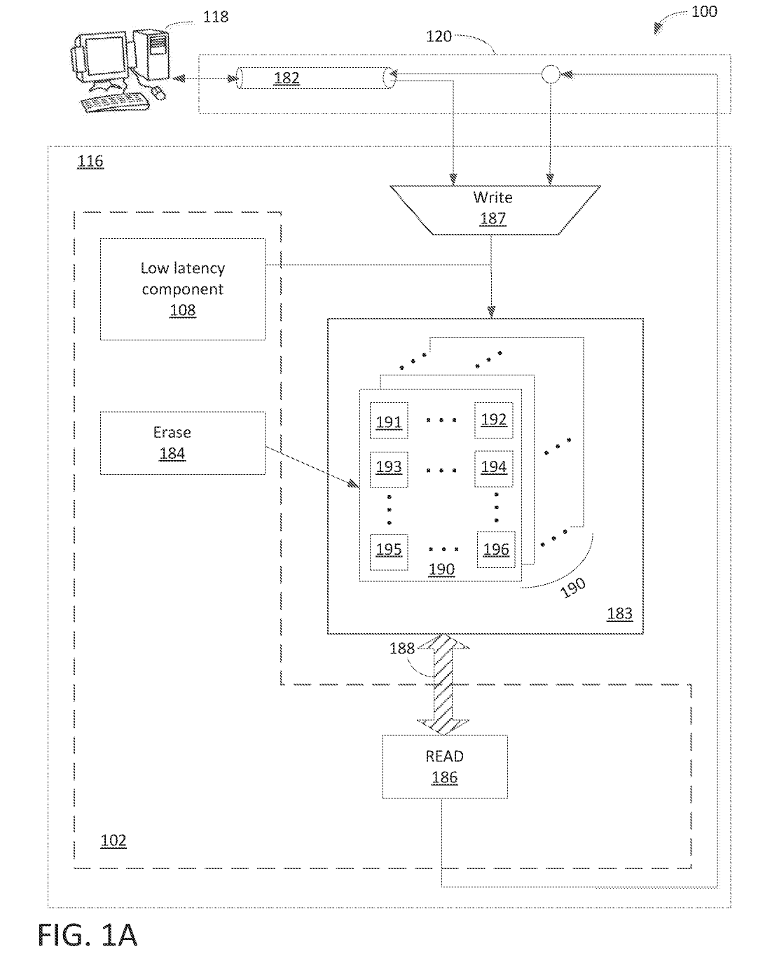

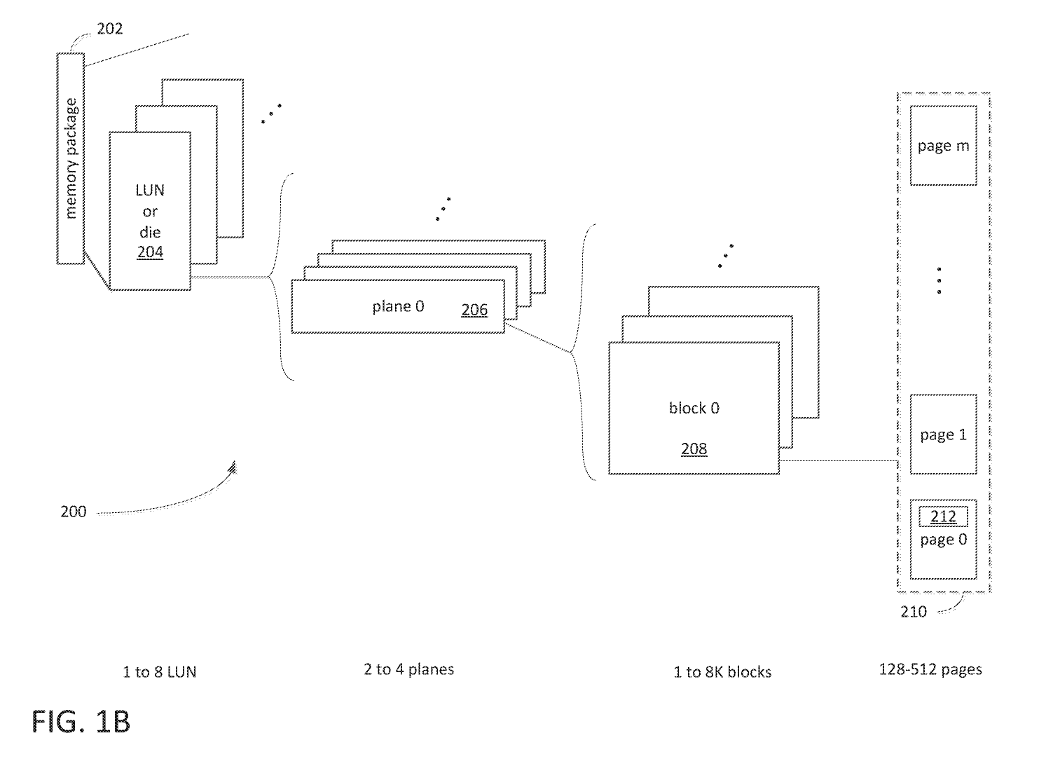

FIG. 1A is a block diagram 100 illustrating a host system able to access NVM in an SSD with low latency access time in accordance with one embodiment of the present invention. Diagram 100 includes a host system 118, bus 120, and SSD 116 which further includes storage device 183, output port 188, and storage controller 102. Bus 120 can be Peripheral Component Interconnect Express (“PCIe”) bus capable of transmitting and receiving data 182 between host system 118 and SSD 116. Storage controller 102 further includes read module 186 and/or write module 187. Diagram 100 also includes an erase module 184 which can be part of storage controller 102 for erasing or recycling used NVM blocks. It should be noted that the underlying concept of the exemplary embodiment(s) of the present invention would not change if one or more blocks (or devices) were added to or removed from diagram 100.

Storage device 183, in one example, includes a flash memory based NVM used in SSD 116. The flash memory cells are organized in multiple arrays for storing information persistently. The flash memory, which generally has a read latency less than 100 microseconds (“μs”), can be organized in logic units (“LUN”), planes, blocks, and pages. A minimum access unit such as read or write operations, for example, can be set to a page or NAND flash page which can be four (4) kilobyte (“Kbyte”), eight (8) Kbyte, or sixteen (16) Kbyte memory capacity depending on the flash memory technology employed. A minimum unit of erasing used NAND flash memory is generally a block or NVM block at a time. An NVM block, in one example, can contain from 512 to 2048 pages.

It should be noted that other types of NVM can be used in place of the flash memory. For example, the other types of NVM includes, but not limited to, phase change memory (“PCM”), magnetic RAM (“MRAM”), STT-MRAM, or ReRAM, which can also be used in storage device 183. It should be noted that a storage system can contain multiple storage devices such as storage devices 183. To simplify the forgoing discussion, the flash memory or flash memory based SSD is herein used as an exemplary NV storage device.

Storage device 183, in one embodiment, includes multiple flash memory blocks (“FMBs”) 190. Each of FMBs 190 further includes a set of pages 191-196 wherein each page such as page 191 has a flash page size of 4K bytes to 16 Kbyte. In one example, FMBs 190 can contain from 512 to 2048 flash pages. A page is generally a minimal programmable unit. A sector is generally a minimal readable unit. Blocks or FMBs 190 are able to persistently retain information or data for a long period of time without power supply.

Memory controller, storage controller, or controller 102, in one embodiment, includes a low latency component (“LLC”) 108 wherein LLC 108 is able to improve read and/or write latency. LLC 108, in one aspect, is able to provide low latency memory access using MCS, HCP, CCA, LBE, or a combination of MCS, HCP, CCA, and/or LBE approach(s). The MCS approach, for example, activates the controller to constantly snoop or monitor the submission queue for any new SQEs whereby the process of doorbell ringing can be omitted. The HCP approach allows a host central processing unit (“CPU”) continuously polling CQE(s) from the completion queue whereby the process of doorbell ringing newly arrived CQE can be eliminated. The CCA approach allows the host system to cache the content of write operation whereby the NVM programming impediment can be reduced. The LBE approach executes an erasing operation before execution of a write command.

Erase module 184, in one embodiment, is able to preserve the page status table between erase operations performed to each block. Erase module 184 is able to schedule when the blocks in LUN should be erased. Before erasing, erase module 184 can also be configured to be responsible for carrying out garbage collection process. Garbage collection processing, in one example, is to extract valid page(s) from a block that has marked for recycling.

FTL, also known as FTL table, is an address mapping table. FTL includes multiple entries which are used for NVM memory accessing. Each entry of the FTL table, for example, stores a physical page addresses (PPA) addressing a physical page in the NVM. A function of FTL is to map logical block addresses (“LBAs”) to physical page addresses (“PPAs”) whereby the PPA(s) can be accessed by a write or read command. In one aspect, FTL is capable of automatically adjusting access NVM page when the page status table indicates that the original targeted NVM page is defective.

An advantage of employing LLC 108 is to improve read or write latency whereby the performance of overall NVM SSD is enhanced.

FIG. 1B is a block diagram 200 illustrating an exemplary layout for NVM capable of operating low latency memory access in accordance with one embodiment of the present invention. Diagram 200 includes a memory package or storage 202 which can be a memory chip containing one or more NVM dies or logic units (“LUNs”) 204. Memory package 202, in one aspect, is a flash based NVM storage that contains, for example, a hierarchy of Package-Silicon Die/LUN-Plane-Block-Flash Memory Page-Wordline configuration(s). It should be noted that the underlying concept of the exemplary embodiment(s) of the present invention would not change if one or more blocks (or devices) were added to or removed from diagram 200.

The NVM device such as a flash memory package 202, in one example, contains one (1) to eight (8) flash memory dies or LUNs. Each LUN or die 204 can be divided into two (2) to four (4) NVM or flash memory planes 206. For example, die 204 may have a dual planes or quad planes. Each NVM or flash memory plane 206 can further include multiple memory blocks or blocks. In one example, plane 206 can have a range of 1000 to 8000 blocks. Each block such as block 208 includes a range of 512 to 2048 flash pages. For instance, block 210 includes 512 or 2048 NVM pages depending on NVM technologies.

A flash memory page such as page 1, for example, has a memory capacity from 8 KBytes to 16 KBytes plus extra redundant area for management purposes such as ECC parity bits and/or FTL tables. Each NVM block, for instance, contains from 512 to 2048 NVM pages. In an operation, a flash memory block is the minimum unit of erase and a flash memory page is the minimum unit of program (or write) and read.

A characteristic of LUN is that when a block within the LUN is being programmed or erased, the read operations for any other blocks within the LUN have to wait until the programming or erasing operation is complete. In general, an NVM read operation takes less time than an NVM write operation. Similarly, an NVM read operation normally takes less than 10% of the time required for performing an NVM write operation.

Accordingly, scheduling confined NVM write or erase operation(s) can improve overall SSD performance.

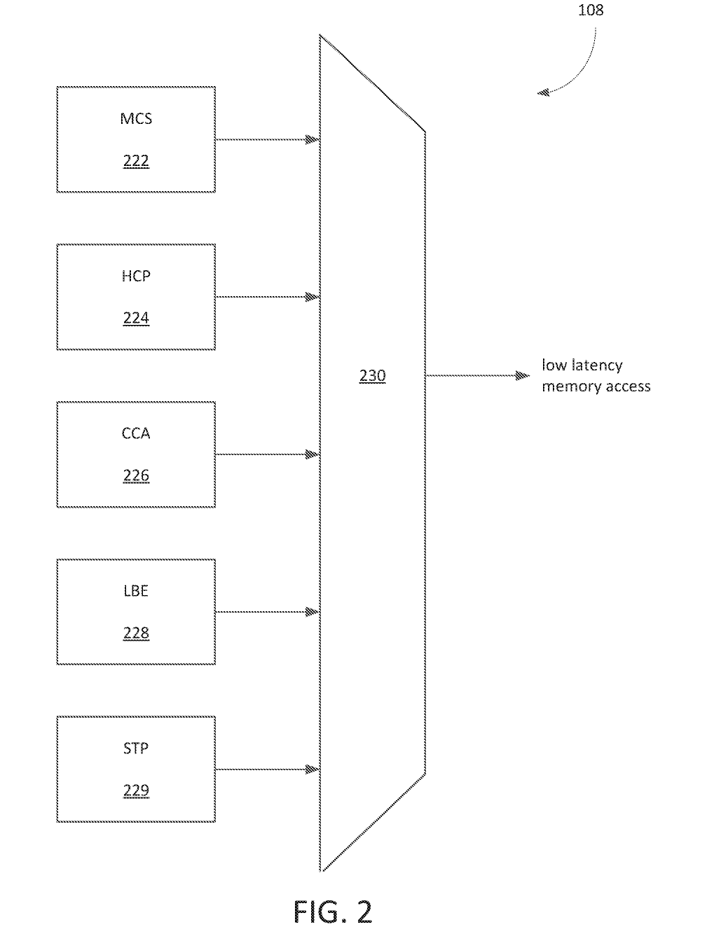

FIG. 2 is a block diagram illustrating LLC 108 containing MCS, HCP, CCA, LBE, or a combination of MCS, HCP, CCA, LBE, and/or STP components capable of providing low latency memory access in accordance with one embodiment of the present invention. LLC 108, in one embodiment, includes MCS 222, HCP 224, CCA 226, LBE 228, STP 229, and/or multiplexer (“Mux”) 230. Depending on the applications, LLC 108 uses Mux 230 to pick and choose which one of MCS 222, HCP 224, CCA 226, LBE 228, and STP 229 may be used to optimize low latency access. Alternatively, all of MCS 222, HCP 224, CCA 226, LBE 228, and STP 229 may be used to deliver low latency memory accesses.

The MCS operation, in one embodiment, provides a process of low latency non-volatile memory access to NVM of SSD using snooping process to identify SQE(s) in SQ. For instance, upon pushing an SQE write by host CPU from host to SQ which is viewable by the controller of SSD, the counter value of SQ header pointer is incremented to reflect storage of the SQE in SQ. After detecting the SQE in SQ by a snooping component in the memory controller in accordance with SQ header pointer, the SQE is cached by the controller and one or more SSD memory instructions are subsequently executed in response to content of the SQE.

The HCP operation, in one aspect, is a process for low latency memory access to an NVM of SSD using polling of CQE in CQ. For example, after generating a CQE in accordance with the result of performance of the SSD memory access, the CQE is stored or deposited to CQ which is viewable by the host. Upon polling periodically to CQ by the host to identify whether the CQE is present in response to earlier SQE, the CQE is fetched from CQ upon detection of the CQE via the polling activity. The host subsequently obtains the result of the performance based on the CQE.

The CCA operation is a method for low latency memory access to an SSD using a scheme of caching write content. For example, upon confining writing process associated with the write command to one (1) LUN in the SSD at a given time for performing the write commands, the content is written from the host to the LUN in accordance with the write commands. After caching the content associated with the write command to a cache while the content is copied to the LUN, the host can still access the content via the cache while the LUN is programmed for storing the content.

The LBE operation, in one embodiment, is a process for low latency memory access to an SSD configured to perform an erase before write operation. For example, after identifying a first LUN in SSD as a destination storage location for the write command, all blocks within the first LUN is erased. Upon completion of the erasing process, the content from the host is programmed or written to the first LUN in accordance with the write command.

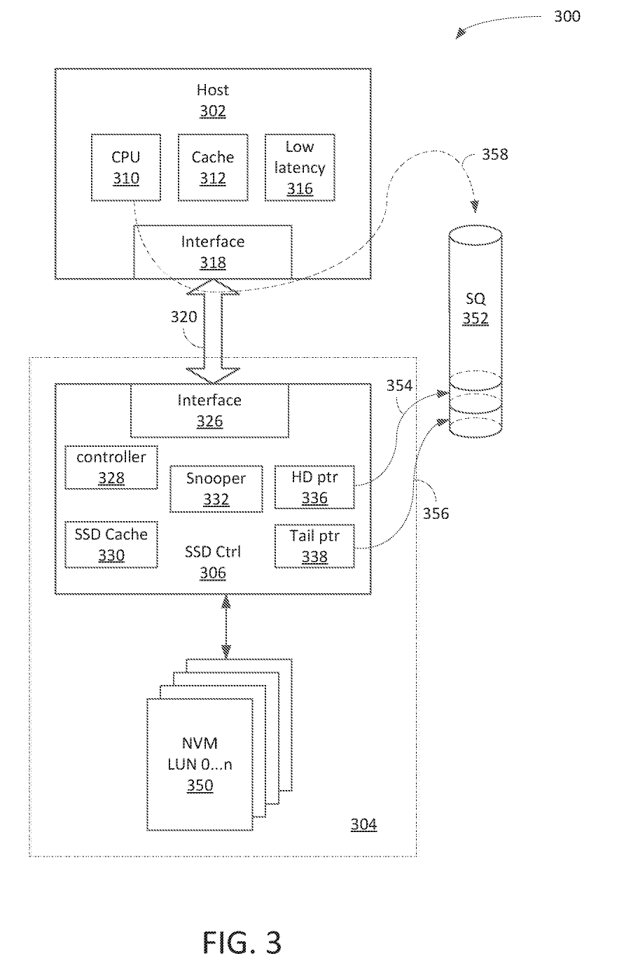

FIG. 3 is a block diagram 300 illustrating a data storage system including host 302 and SSD 304 capable of providing low latency memory accesses using a MCS approach in accordance with one embodiment of the present invention. Diagram 300 includes host 302, SSD 304, external bus 320, and SQ 352 wherein SQ 352, in one aspect, resides in host 302. Alternatively, SQ can also reside in SSD or controller attached memory buffer. A function of the data storage system is to store and/or retrieve large amount of data quickly. It should be noted that the underlying concept of the exemplary embodiment(s) of the present invention would not change if one or more blocks (or devices) were added to or removed from diagram 300.

Host 302, which can also be referred to as a host system, host computer, or host CPU, can be a server, desktop, laptop, mini-computer, mainframe computer, work station, network devices, router, switch, automobile, smart phone, or a cluster of server, desktop, laptop, mini-computer, mainframe computer, work station, network device, router, switch, and/or smart phone. Host 302, in one embodiment, includes CPU 310, cache 312, low latency circuit 316, and interface 318 which is used to communicate with bus 320. CPU 310, for example, is a digital processing component capable of executing instructions. Cache 312 is a volatile memory which can be used to cache a portion of data or information stored in a main memory (not shown in FIG. 3).

To facilitate MCS operation, host 302, in one aspect, employs a low latency circuit 316 which can be part of LLC 108 as shown in FIG. 1. A function of low latency circuit 316 is to manage low latency implementations in concert with SSD. For example, low latency circuit 316 can monitor and/or facilitate pushing or polling operations between SQ and CQ. To communicate with SSD 304, host 302 uses interface 318 to communicate with SSD via a high-speed serial bus 320.

SQ can be a first-in-first-out or circular buffer with a fixed or flexible memory size that a host system or host uses for command submissions by a controller. Generally, the host may deposit information to an SQ tail doorbell register when one to more commands need to be execute. Note that previous SQ tail value may be changed in a controller when the new doorbell register write has been written. It should be noted that each SQE is at least one memory command.

Bus 320, in one example, can be a high-speed and high-bandwidth serial bus such as a PCI Express (Peripheral Component Interconnect Express) (“PCIe” or “PCI-e”) bus. Bus 320 or PCIe bus provides high system bus throughput and low pin count with relatively smaller footprint. Bus 320, in one example, also contains error detection capability and hot-pluggable functions. A function of bus 320 or PCIe bus is to facilitate fast data transmission between host 302 and SSD 304.

SSD 304, in one embodiment, includes an SSD controller 306 and NVM storage 350 wherein NVM storage 350 is organized into multiple LUNs. A function of SSD is to store large amount of data persistently. To facilitate low latency memory access, SSD 304, in one embodiment, employs MCS scheme to reduce NVM read or write latency.

To provide MCS, SSD controller 306, in one embodiment, includes a controller 328, SSD cache 330, snooper 332, head pointer (“HD ptr”) 336, tail pointer 338, and SSD interface 326 wherein SSD interface 326 is used to communicate with host 302 via bus 320. Controller 328 manages various NVM functions, such as, but not limited to, garbage collections, read function, write function, erase function, snooping function, interface function, and the like. SSD Cache 330 is used to temporarily cache a portion of the stored information in NVM storage 350 to improve memory access speed. While HD ptr 336 may be used to point to the header (or top) of SQ 352, tail ptr 338 points to the tail (or bottom) of SQ 352.

SQ 352, in one embodiment, is established to store submission queue entry(s) or SQEs wherein each SQE, for example, is a memory access issued by host 302. For instance, an SQE can be a read command with an address or addresses where the reading content is stored in NVM storage 350. SQ 352, in one aspect, is located in host 302 wherein the entries of SQ are viewable or accessible by SSD 304. Alternatively, SQ 352 can be placed in SSD 304 wherein the entries of SQ are viewable or accessible by host 302. In an alternative embodiment, SQ 352 is located at the controller attached memory buffer which, in one aspect, is in NVM assigned to bus 320. In yet another embodiment, SQ 352 can be located at a designated storage location which is independent from host CPU 302 as well as SSD 304.

During an operation, host 302 deposits an SQE in SQ 352 for a memory access as indicated by numeral 358. After storing the SQE in SQ 352, HD ptr 336 is incremented as indicated by numeral 354 to reflect the newly arrived SQE. Upon detecting the difference between HD ptr 336 and tail ptr 338, the SQE in SQ 352 is verified. It should be noted that since SQ 352 is visible or viewable by SSD controller 306 via snooper 332, a load or DMA is initiated by SSD controller to obtain the SQE. After obtaining the SQE, the memory access based on the SQE is implemented.

An advantage of using the MCS approach using snooper 332, HD ptr 336, and tail ptr 338 is that MCS approach snoops SQ 352 for SQE deposit whereby the process of doorbell can be reduced, omitted, and/or eliminated.

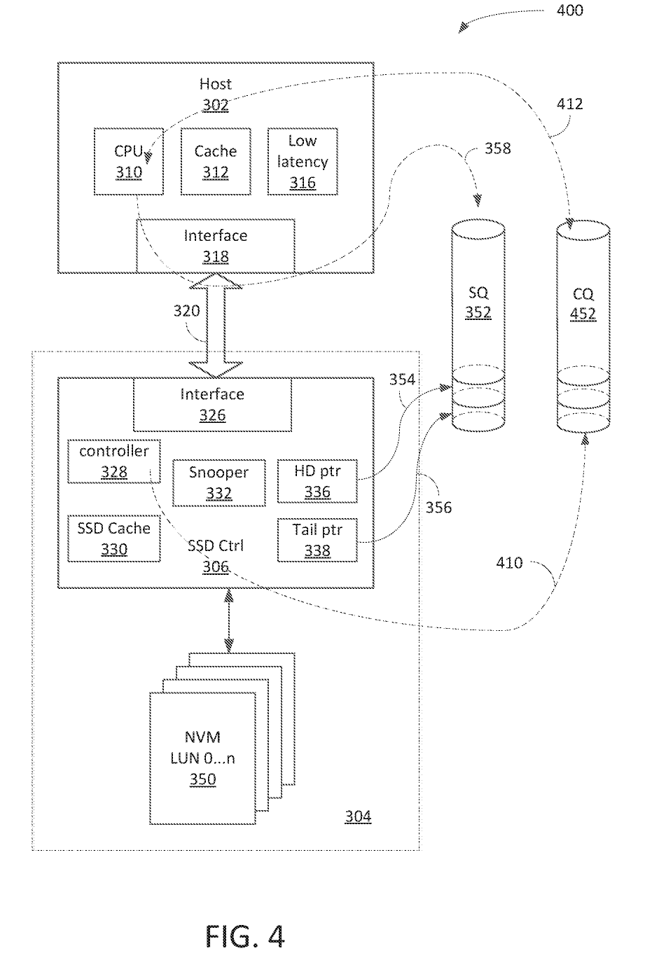

FIG. 4 is a block diagram 400 illustrating a storage system containing a host and SSD capable of providing low latency memory access using a HCP approach in accordance with one embodiment of the present invention. Diagram 400 includes host 302, SSD 304, external bus 320, SQ 352, and CQ 452 wherein CQ 452, in one aspect, resides in host 302. Alternatively, CQ 452 can reside in SSD or controller attached memory buffer. A function of the data storage system is to store and/or retrieve large amount of data quickly. It should be noted that the underlying concept of the exemplary embodiment(s) of the present invention would not change if one or more blocks (or devices) were added to or removed from diagram 400.

Diagram 400, in one embodiment, is similar to diagram 300 shown in FIG. 3 except that diagram 400 further includes CQ 452 for facilitating HCP operation. To support HCP operation, host 302, in one aspect, employs CPU 310 and/or low latency circuit 316 which could be part of LLC 108 as shown in FIG. 1 to manage the polling process of CQ 452. For example, CPU 310 and/or low latency circuit 316 may be configured to manage low latency implementations in concert with SSD. A function of CPU 310 or low latency circuit 316 is to monitor and/or facilitate pushing and/or polling operation between SQ 352 and CQ 452.

To facilitate or support HCP operation(s), controller 328 is used to manage, deposit, and/or store data or result formatted as completion queue entry(s) (“CQEs”) to CQ 452. CQEs, for example, are the results in response to earlier SQEs. For instance, a CQE which is stored or deposited by controller 328 to CQ 452 can indicate which memory command has been completed. CQE is an entry in CQ that describes the information about the completed work or task request(s) such as a memory access. For example, CQE may indicate a completed command that is identified by an associated SQ identifier and command identifier. It should be noted that multiple SQEs can be associated with a single CQE. CQ 452 can be a first-in-first-out (FIFO) or circular buffer which is associated with a queue used to receive completion tasks, notifications, results, and/or events.

CQ 452, in one embodiment, is established or designated to store CQEs wherein each CQE, for example, is a result in response to an earlier memory access request issued by host 302. For instance, an SQE can be a write command with an address or addresses where the write content should be stored to a location in NVM storage 350. CQE, in this example, is a result of the write command indicating that the write command has been successfully performed or failed. CQ 452, in one aspect, is located in host 302 wherein the entries of SQ are viewable or accessible by SSD 304. Alternatively, CQ 452 can be placed in SSD 304 wherein the entries of CQ are viewable or accessible by host 302. In an alternative embodiment, CQ 452 is located at the controller attached memory buffer which, in one aspect, is in NVM assigned to bus 320. In yet another embodiment, CQ 452 can be located at a designated storage location which is independent from host CPU 302 as well as SSD 304.

During an operation, SSD controller 306 performs a memory access or low latency memory access based on an SQE initiated and/or deposited by host 302. After generating a result or results based on the SQE, controller 328 generates a CQE reflecting the result of earlier SQE. The CQE is subsequently stored or deposited in CQ 452 as indicated by numeral 410. Since CQ 452 is visible or viewable to CPU 310, HCP activates a polling process which constantly polls information from CQ 452 to determine whether any new arrivals of CQEs as indicated by 412. It should be noted that the HCP process can enhance overall memory access latency time because the handshake between host 302 and SSD 304 is simplified.

An advantage of using the HCP approach is that HCP is able to establish a host-SSD communication without using any interrupt service routines whereby the overall performance of SSD is enhanced.

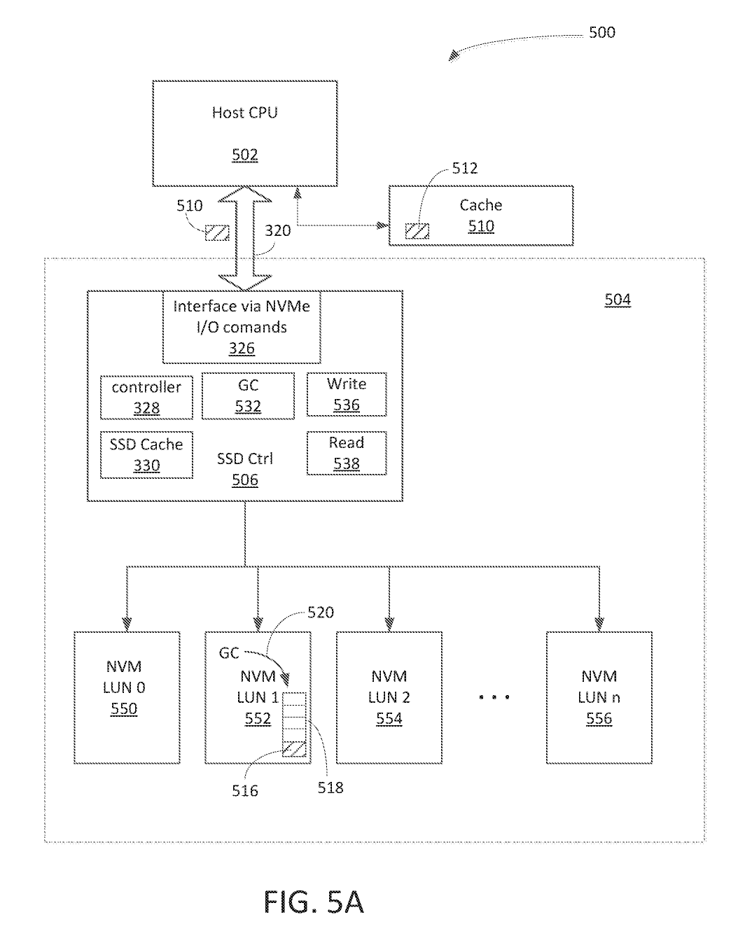

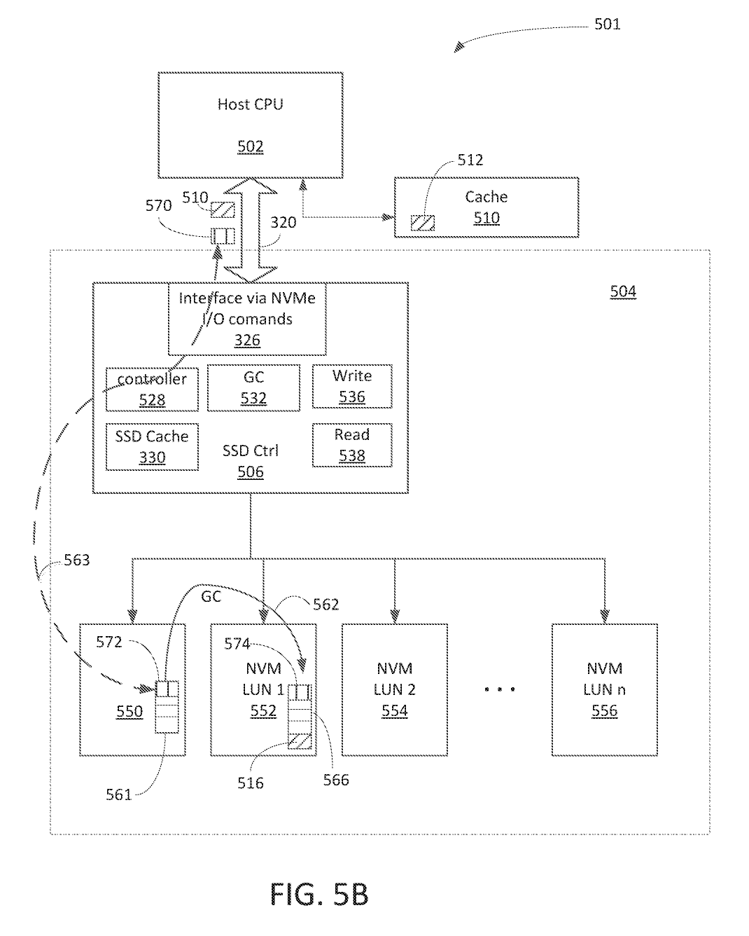

FIG. 5A is a block diagram 500 illustrating a data storage system containing a host and SSD capable of providing low latency memory access using a CCA approach in accordance with one embodiment of the present invention. Diagram 500 includes host 502, SSD 504, external bus 320, and cache 510 wherein cache 510, in one aspect, resides in host 502. Alternatively, cache 510 can reside in SSD 504 or controller attached memory buffer. Cache 510, in another embodiment, can be an independent storage device independent from host 502 and SSD 504. A function of the data storage system is to store and/or retrieve large amount of data quickly. It should be noted that the underlying concept of the exemplary embodiment(s) of the present invention would not change if one or more blocks (or devices) were added to or removed from diagram 500.

Host 502, which is the same or similar to host 302 illustrated in FIG. 3, can a server, desktop, laptop, mini-computer, mainframe computer, work station, network devices, router, switch, automobile, smart phone, or a cluster of server, desktop, laptop, mini-computer, mainframe computer, work station, network device, router, switch, and/or smart phone. To facilitate CCA operation, host 502, in one embodiment, uses cache 510 to store the content of a write operation 512 whereby host 502 can continue accessing content of the write operation 512 while the write operation is being carried out by SSD as indicated by numeral 510.

SSD 504, in one embodiment, includes an SSD controller 506 and NVM storage wherein NVM storage is organized into multiple LUNs 550-556. A function of SSD is to store large amount of data persistently. To facilitate low latency memory access, SSD 504, in one embodiment, employs CCA to reduce NVM read or write latency.

SSD controller 506, in one embodiment, includes a controller 328, SSD cache 330, garbage collection (“GC”) 532, write component 536, read component 538, and SSD interface 326 wherein SSD interface 326 is used to communicate with host 302 via bus 320. In one aspect, cache 510 can be part of SSD cache 330. Controller 328 manages various NVM functions, such as, but not limited to, garbage collections, read function, write function, erase function, caching function, interface function, and the like.

GC 532, in one embodiment, includes a garbage collection manager configured to recover storage space based on predefined GC triggering events. With the scanning capability, GC 532 is able to generate a list of garbage block identifiers. GC 532 is also able to identify valid page within one or more of the garbage block IDs. In one example, the valid pages are subsequently moved to another LUN before the block is being erased. It should be noted that when a file is deleted, SSD or flash NVM is required to erase the unneeded data blocks before new data can be written. GC process is a necessary procedure for every flash based SSD to recycle blocks or LUN that contains old and/or obsolete data.

To facilitate CCA operation, SSD controller 506, in one embodiment, is able to identify a targeted LUN associated with a memory access and performing a write implementation while allowing host 502 to continue access the content of write operation in cache 510. To further improve the efficiency, CCA can combine the GC process and write operation while allowing host 502 to access useful content in the targeted LUN via cache 510.

It should be noted that a typical read can take about 10s microseconds (μs). While program blocking can take about 100s μs, erase blocking can take around 1,000s By doing a write cache on a host CPU memory side, data can be read from host CPU write cache when data is programmed to the LUN and erased. Note that all reads will be from the LUN that has no program and erase blocking. The latency for a read operation should be around or less than 10 μs because QD (queue depth) should be around one (1).

During an operation, host 502 issues a write operation with content 510 and LUN 1. After storing content 510 to cache 510 as content 512, SSD controller 506 writes content 510 into LUN 1 as content 516 while content 512 is available to host 502. In one embodiment, SSD controller 506 further manages a GC process 520 such as moving some valid pages 518 from other LUNs into LUN 1.

An advantage of using the CCA approach is that CCA is able to minimize write blocking, program blocking, and/or erase blocking whereby overall SSD performance is enhanced.

FIG. 5B is a block diagram 501 illustrating a data storage system containing a host and SSD capable of providing low latency memory access using an access erase-marked LUN (“AEL”) approach in accordance with one embodiment of the present invention. Diagram 501, which is similar to diagram 500 shown in FIG. 5A, includes host 502, SSD 504, external bus 320, and cache 510 wherein cache 510, in one aspect, resides in host 502. A function of the data storage system is to store and/or retrieve large amount of data quickly. It should be noted that the underlying concept of the exemplary embodiment(s) of the present invention would not change if one or more blocks (or devices) were added to or removed from diagram 501.

SSD controller 506, in one embodiment, includes a controller 528, SSD cache 330, garbage collection (“GC”) 532, write component 536, read component 538, and SSD interface 326 wherein SSD interface 326 is used to communicate with host 302 via bus 320. In one aspect, cache 510 can be part of SSD cache 330. Controller 528 manages various NVM functions, such as, but not limited to, garbage collections, read function, write function, erase function, caching function, interface function, and the like. In one aspect, controller 528 is capable of facilitating AEL process to reduce memory access time during GC process.

SSD 504, in one aspect, includes a group of NVM LUNs 550-556 wherein LUN 550 is an erase-marked LUN while LUN 552 is a targeted LUN. The erase-marked LUN, for example, is an LUN containing valid pages and old blocks that has been designed or marked as recycle LUN or old LUN. In one embodiment, GC 562 is able to identify valid sectors within one or more garbage block IDs in LUN 550. To process a GC process, valid sectors in LUN 0 are moved to LUN 552 as the targeted LUN before the blocks in LUN 550 is being erased. It should be noted that when a file is deleted, SSD or flash NVM is required to erase the unneeded data blocks before new data can be written. Note that the GC process is a necessary procedure for every flash based SSD to recycle blocks or LUN that contains old and/or obsolete data.

To facilitate AEL operation, SSD controller 506, in one embodiment, is able to identify targeted LUN 552 associated with a memory access and subsequently performs a read operation as indicated by numeral 570 reading data 572 from valid page of erase-marked block or LUN 550 while valid pages 561 are continuously moved from the erase-marked block (i.e., LUN 550) to targeted LUN 552.

During an operation, host 502, for example, issues a read operation 570 for reading content 574 in LUN 552. After detecting GC process 562 moving valid pages 561 from erase-marked LUN 550 to pages 566 in LUN 552, controller 528 with firmware and FTL obtains content 572 which is the same as content 574 in the erase-marked LUN 550 as indicated by arrow 563.

An advantage of using the AEL approach is that AEL enables host to read data from erase-marked LUN before the completion of GC process.

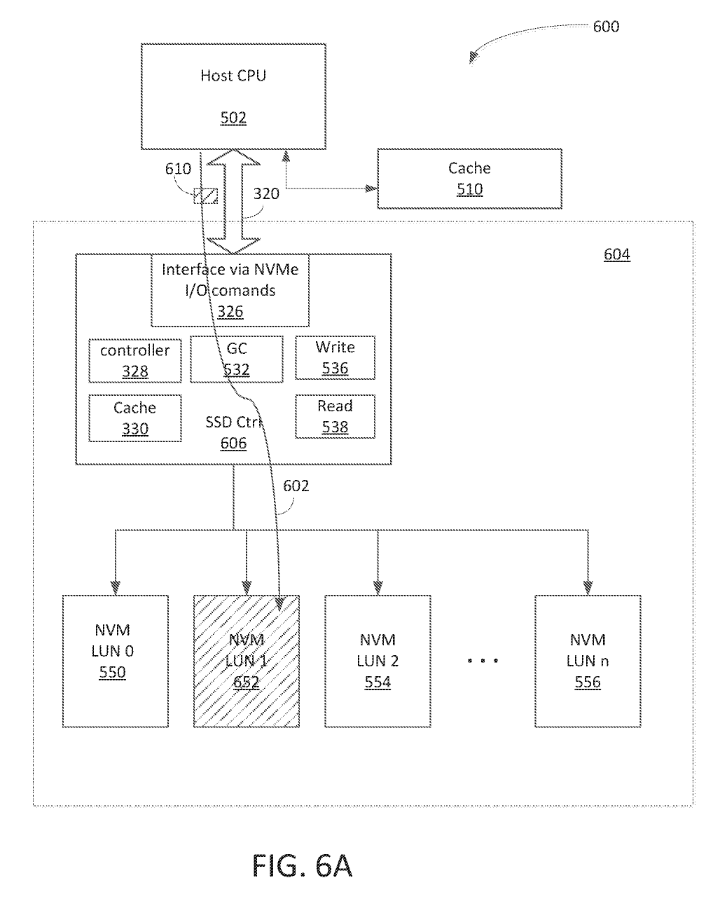

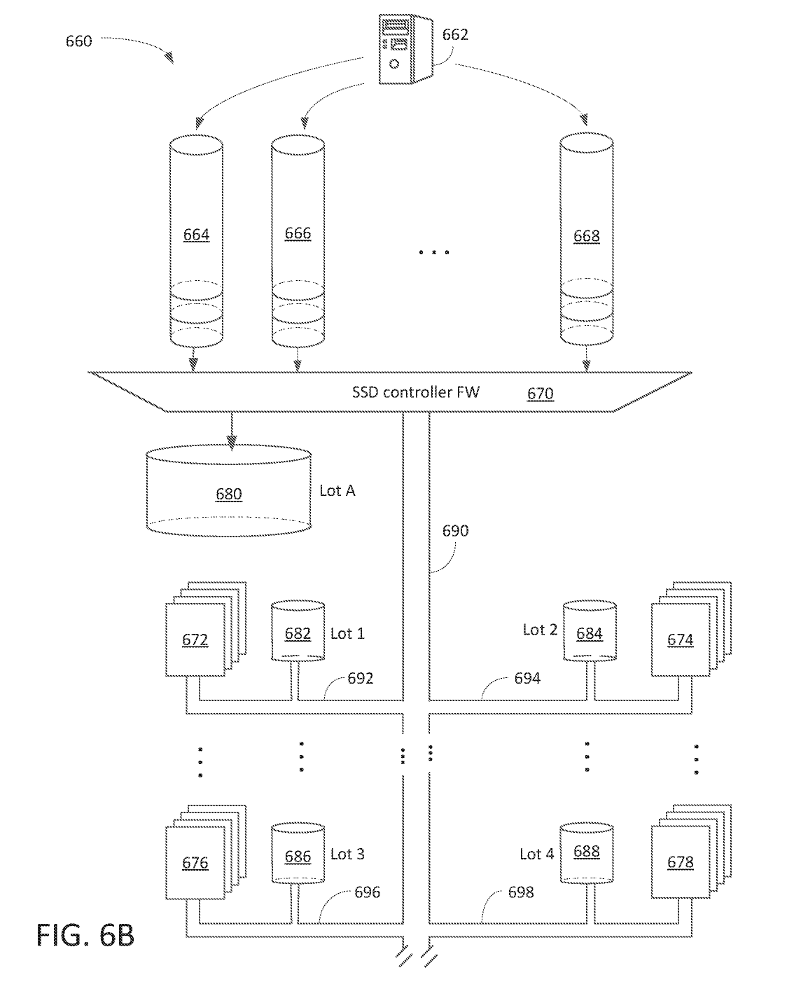

FIG. 6A is a block diagram 600 illustrating a data storage system containing a host and SSD capable of providing low latency memory access using a LBE approach in accordance with one embodiment of the present invention. Diagram 600 includes host 502, SSD 604, external bus 320, and cache 510 wherein cache 510, in one aspect, resides in host 502. A function of the data storage system is to store and/or retrieve large amount of data quickly. It should be noted that the underlying concept of the exemplary embodiment(s) of the present invention would not change if one or more blocks (or devices) were added to or removed from diagram 600.

Diagram 600 is similar or same as diagram 500 shown in FIG. 5 except that SSD controller 606 is configured to implement LBE operation to further control and/or minimize memory access time. In one embodiment, the LBE scheme is to perform an erase operation to an LUN before a write operation is executed with respective to the LUN. A benefit of performing an erase operation before a write operation is to reduce erase blocking read or write during GC process during a write operation. For example, after receiving a write command for an SSD memory access, a targeted LUN is identified as a destination storage location for the write command, all blocks within the LUN is erased first. Upon completion of the erasing process, the content from the host is programmed or written to the erased and freed up LUN in accordance with the write command.

To support low latency NVMe SSD, one LUN is programmed at a given time in which the read will not be blocked by program. By applying GC (garbage collection) to a LUN which is not read, the read operation will not be blocked by erase but may be blocked by program. In one example, one LUN is being erased at one time when FTL table is updated and LUN has VPC (valid page count) equals to zero (0). It should be noted that by using the strategy of updating the FTL map table after the whole LUN is programmed, program blocking due to GC may be avoided. Note that the host data that is programmed into LUN can be read with program blocking. In one example, when SSD controller applies garbage collection, the data is copied to one LUN at a time before the LUN is fully programmed. After updating FTL L2P table, the program blocking can be avoided which could cause 10 times or more latency jitter. In one embodiment, before a LUN is started programming, all blocks in that LUN is erased so that we can avoid erase blocking. The erase blocking time can be as much as over 1000 times of read latency.

In operation, when host 502 issues a write operation with content 610, SSD controller 606 identifies which LUN is the intended storage location. Upon identifying LUN 1 is the targeted LUN 652, an erase operation is first performed to LUN 1. After erase operation, content 610 is programmed or written to LUN 1.

An advantage of employing LBE is that LBE operation can reduce or avoid erase blocking.

FIG. 6B is a block diagram 660 illustrating a host and SSD capable of providing low latency memory access using a SQE temporarily parking (“STP”) approach in accordance with one embodiment of the present invention. Diagram 660 includes a host 662, SQs 664-668, SSD controller 670, global temporarily parking lot (“TPL”) 680, local TPLs 682-688, LUNs 672-678, global bus 690, and local buses 692-698. SQs 664-668, in one embodiment, are configured to store or buffer SQEs generated by host 662. It should be noted that the underlying concept of the exemplary embodiment(s) of the present invention would not change if one or more blocks (or devices) were added to or removed from diagram 660.

In one aspect, each LUN has a dedicated local TPL for temporarily parking an SQE when the LUN is busy. Lot A or global TPL 680 is configured to temporarily store SQE(s) when one of the local TPLs 684-688 is full. A function of TPL is to reduce traffic congestion.

SSD controller 670, in one embodiment, is configured to perform STP operation to shorten the memory access time by reducing traffic congestions in global bus 690 and/or local buses 692-698. To provide STP operation, SSD controller 670 uses its firmware and/or FTL table to monitor LUN current status which includes, but not limited to, writing activity(s), GC programming(s), reading(s), and/or queue(s). To reduce traffic congestions, SSD controller 670 is able to park or buffer an SQE at a local TPL such as local TPL 684 if LUN 674 is busy performing other functions such as GC programming. In the event that the local TPL is full, SSD controller 670 can park or store the SQE at global TPL 680 which has large storage capacity.

During an operation, upon receipt of an SQE from SQ 666, SSD controller 670 determines that the SQE is a write operation writing content to LUN 676. After identifying that LUN 676 is busy, the SQE is stored or parked at lot 3 or local TPL 686. If local TPL 686 is full, SSD controller 670 stores or parks the SQE at lot A or global TPL 680. When local TPL 686 is open (or less full), the SQE is moved from global TPL 680 to local TPL 686.

An advantage of using STP approach is that it can improve SQEs latency impact by reducing the head of line blocking effect on the follow-on SQE commands in the same and different SQ.

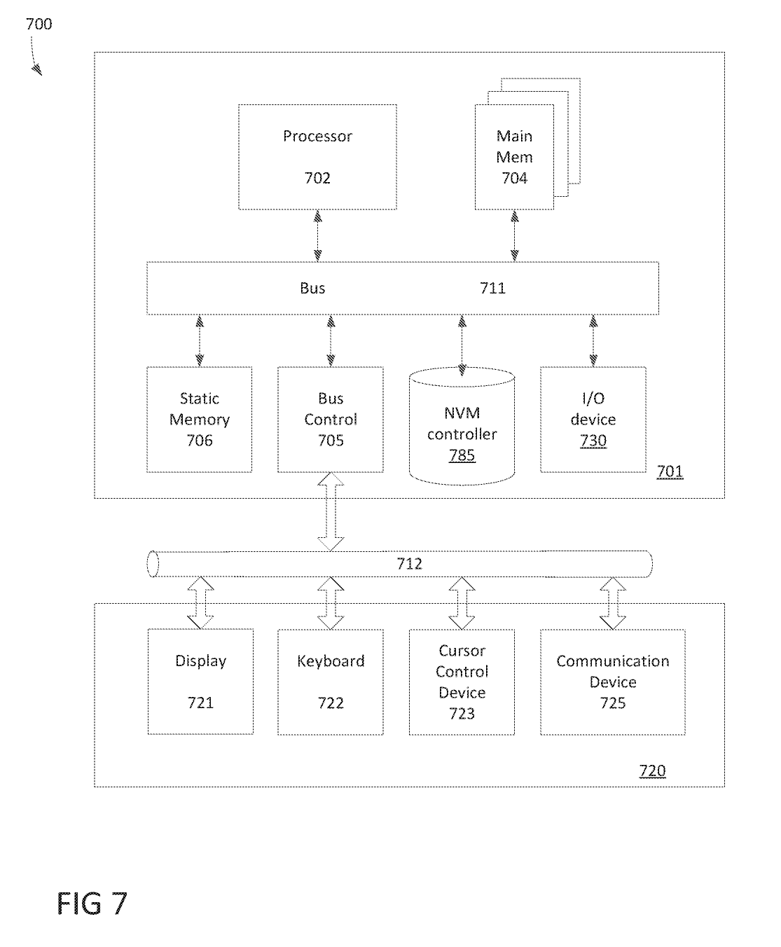

FIG. 7 is a block diagram 700 illustrating a host or memory controller capable of providing low latency memory access in accordance with one embodiment of the present invention. Computer system 700 can include a processing unit 701, an interface bus 712, and an input/output (“IO”) unit 720. Processing unit 701 includes a processor 702, a main memory 704, a system bus 711, a static memory device 706, a bus control unit 705, an I/O element 730, and a NVM controller 785. It should be noted that the underlying concept of the exemplary embodiment(s) of the present invention would not change if one or more blocks (circuit or elements) were added to or removed from diagram 700.

Bus 711 is used to transmit information between various components and processor 702 for data processing. Processor 702 may be any of a wide variety of general-purpose processors, embedded processors, or microprocessors such as ARM® embedded processors, Intel® Core™ Duo, Core™ Quad, Xeon®, Pentium™ microprocessor, Motorola™ 68040, AMD® family processors, or Power PC™ microprocessor.

Main memory 704, which may include multiple levels of cache memories, stores frequently used data and instructions. Main memory 704 may be RAM (random access memory), MRAM (magnetic RAM), or flash memory. Static memory 706 may be a ROM (read-only memory), which is coupled to bus 711, for storing static information and/or instructions. Bus control unit 705 is coupled to buses 711-712 and controls which component, such as main memory 704 or processor 702, can use the bus. Bus control unit 705 manages the communications between bus 711 and bus 712. Mass storage memory or SSD 106, which may be a magnetic disk, an optical disk, hard disk drive, floppy disk, CD-ROM, and/or flash memories are used for storing large amounts of data.

I/O unit 720, in one embodiment, includes a display 721, keyboard 722, cursor control device 723, and communication device 725. Display device 721 may be a liquid crystal device, cathode ray tube (“CRT”), touch-screen display, or other suitable display device. Display 721 projects or displays images of a graphical planning board. Keyboard 722 may be a conventional alphanumeric input device for communicating information between computer system 700 and computer operator(s). Another type of user input device is cursor control device 723, such as a conventional mouse, touch mouse, trackball, or other type of cursor for communicating information between system 700 and user(s).

Communication device 725 is coupled to bus 711 for accessing information from remote computers or servers, such as server 104 or other computers, through wide-area network 102. Communication device 725 may include a modem or a network interface device, or other similar devices that facilitate communication between computer 700 and storage network.

NVM controller 785, in one aspect, is configured to communicate and manage internal as well as external NVM storage devices. NVM controller 785 can manage different types NVM memory cells such as flash memory cells and phase change memory cells. For external NVM storage devices, NVM controller 785 further includes I/O interfaces capable of interfacing with a set of peripheral buses, such as a peripheral component interconnect express (“PCI Express” or “PCIe”) bus, a serial Advanced Technology Attachment (“ATA”) bus, a parallel ATA bus, a small computer system interface (“SCSI”), FireWire, Fibre Channel, a Universal Serial Bus (“USB”), a PCIe Advanced Switching (“PCIe-AS”) bus, Infiniband, or the like.

The exemplary embodiment of the present invention includes various processing steps, which will be described below. The steps of the embodiment may be embodied in machine or computer executable instructions. The instructions can be used to cause a general purpose or special purpose system, which is programmed with the instructions, to perform the steps of the exemplary embodiment of the present invention. Alternatively, the steps of the exemplary embodiment of the present invention may be performed by specific hardware components that contain hard-wired logic for performing the steps, or by any combination of programmed computer components and custom hardware components.

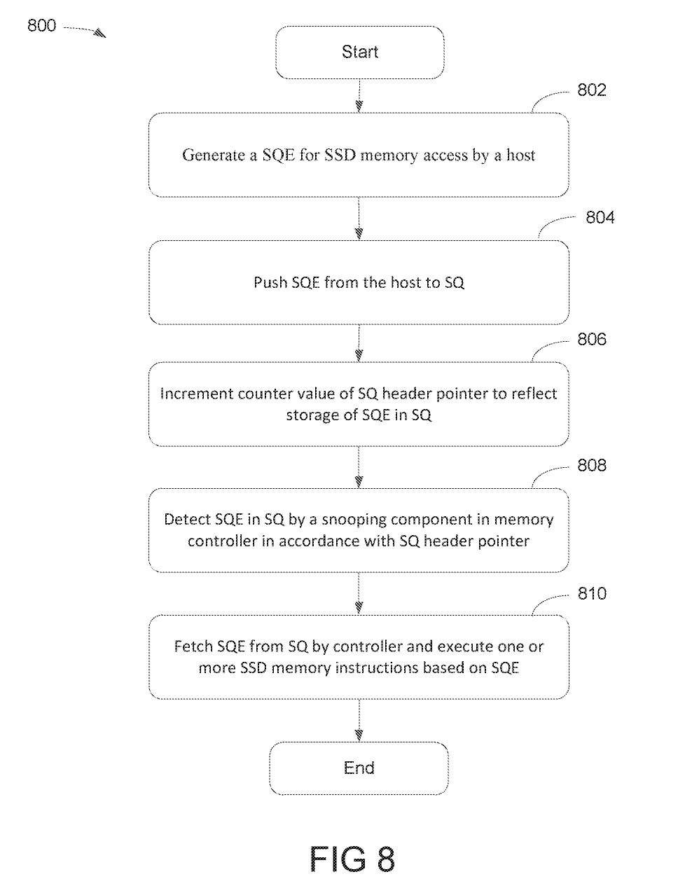

FIG. 8 is a flowchart 800 illustrating a process of providing low latency memory access using an MCS approach in accordance with one embodiment of the present invention. At block 802, a process of MCS capable of providing low latency memory access to NVM SSD is able to generate a first SQE for a first SSD memory access by a host to a connected SSD. It should be noted that the process of MCS can be implemented concurrently with other types of low latency memory access operations, such as HCP, CCA, and/or LBE processes.

After pushing, at block 804, first SQE from the host to SQ which is viewable by the controller of SSD, the MCS, at block 806, increments the counter value of an SQ header pointer to reflect storage of first SQE in SQ. In one example, first SQE is stored at SQ via a PCIe bus connected between host and SSD.

At block 808, first SQE in SQ is detected by a snooping component in the memory controller in accordance with SQ header pointer. In one aspect, the process is capable of identifying the difference between SQ header pointer and an SQ tail pointer by, for example, a comparison module.

At block 810, the SSD controller fetches first SQE from SQ and executes one or more SSD memory instructions in response to content of first SQE. In one embodiment, upon generating a second SQE for a second SSD memory access by host, second SQE is pushed from the host to SQ. After incrementing the counter value of SQ header pointer to reflect storage of the second SQE in SQ, a new DMA operation is initiated to obtain second SQE. In one aspect, SSD or memory controller subsequently performs a first SSD memory access in accordance with first SQE. After generating a first CQE in accordance with a first result of performance of first SSD memory access, the memory controller stores first CQE to CQ which is viewable by the host.

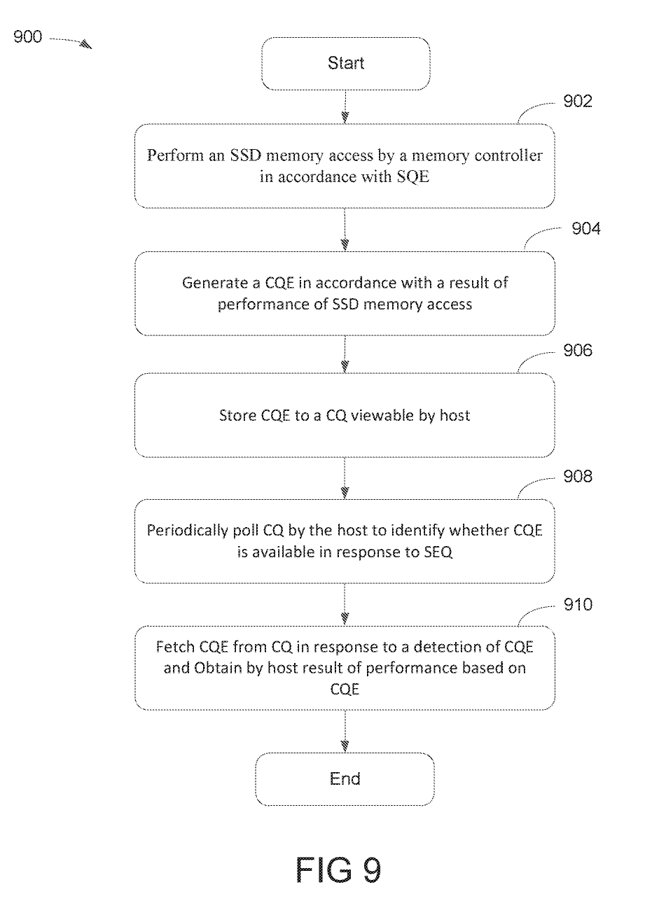

FIG. 9 is a flowchart 900 illustrating a process of providing low latency memory access using an HCP approach in accordance with one embodiment of the present invention. At block 902, a process of HCP capable of facilitating a low latency memory access to NVM SSD is able to perform a first SSD memory access by a controller of SSD in accordance with a first SQE which is imitated or generated by a connected host. After generating a first CQE, at block 904, in accordance with a first result of performance of first SSD memory access, the controller, at block 906, stores first CQE to CQ which is viewable by the host.

The host or host system, at block 908, periodically polls CQ to identify whether first CQE is present in response to first SQE. The first CQE is detected as soon as first CQE arrives at CQ.

At block 910, the host fetches first CQE from CQ upon detection of first CQE by the polling activity. It should be noted that the first result of the performance represented by first CQE is in response to an earlier SQE initiated by the host. For example, after generating a first SQE for a first SSD memory access by the host to SSD, first SQE is pushed by the host to SQ which is viewable by the controller or SSD controller. After incrementing the counter value of SQ header pointer to reflect storage of first SQE in the SQ, first SQE in SQ is detected by a snooping component in the memory controller in accordance with SQ header pointer. The controller or memory controller subsequently fetches first SQE from SQ and executes one or more SSD memory instructions based on content of first SQE.

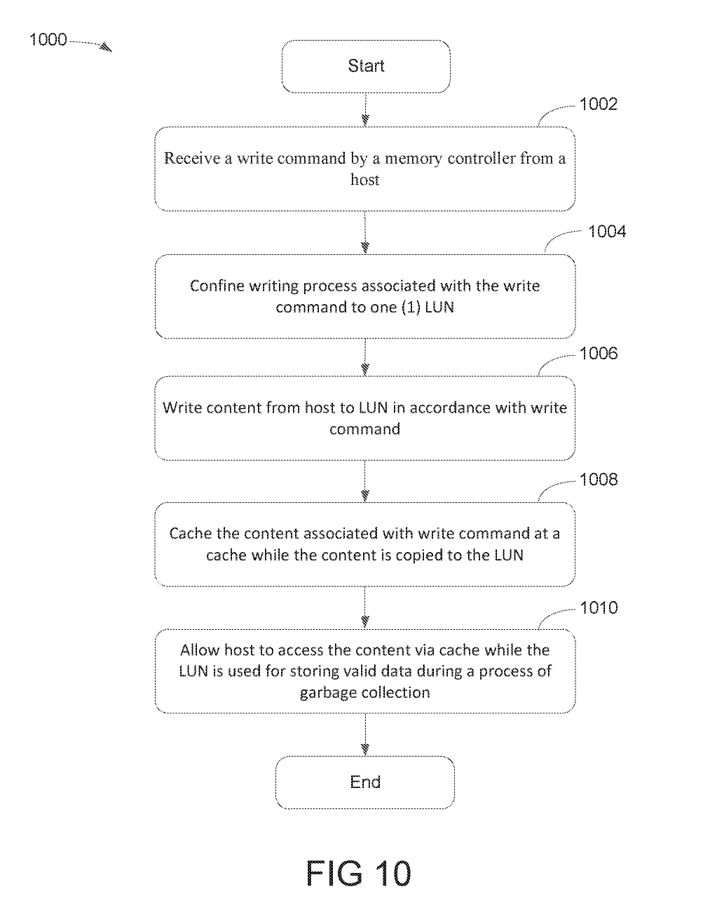

FIG. 10 is a flowchart 1000 illustrating a process of providing low latency memory access using a CCA approach in accordance with one embodiment of the present invention. At block 1002, a process of CCA capable of providing a low latency memory access to NVM SSD is capable of receiving a first write command by a memory controller of SSD from a host for an SSD memory access.

At block 1004, the writing process associated with the first write command, in one embodiment, is confined to one (1) LUN in an SSD at a given time for performing the first write command.

At block 1006, first content is written or stored from the host to the LUN in accordance with the first write command.

At block 1008, the first content associated with the first write command is cached to a local memory cache while the first content is copied to the LUN for providing the first content availability. For example, the first content is stored in a cache located in a host CPU whereby the host can still read or write the first content while the first content is being programmed into the LUN. Alternatively, the first content is stored in a memory cache located in the controller whereby the host can still read or write the first content from a cache in memory controller while the first content is being programmed into the LUN.

At block 1010, the host is allowed to access the first content via the cache while the LUN is programmed for storing the first content. In one aspect, the SSD or LUN programming can also involve in storing valid data during a process of garbage collection. In one embodiment, upon generating the first write command by the host for NVM storage access, the first write command is sent to the SSD via a PCIe bus.

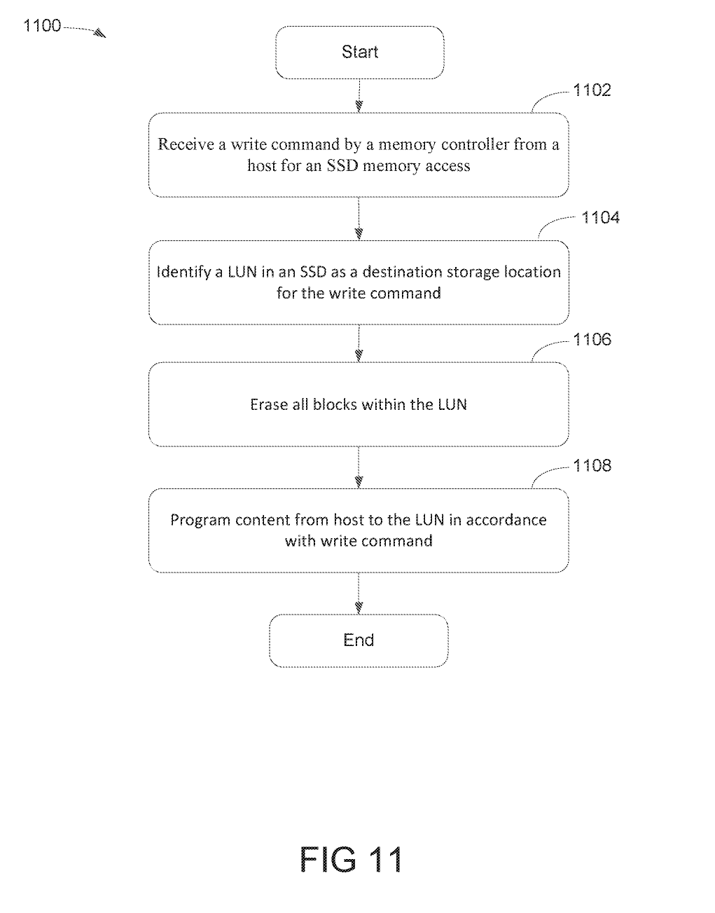

FIG. 11 is a flowchart 1100 illustrating a process of providing low latency memory access using a LBE approach in accordance with one embodiment of the present invention. At block 1102, a process of LBE able to facilitate a low latency memory access to NVM SSD is able to receive a first write command by a memory controller from a host for an SSD memory access.

At block 1104, a first LUN is identified in an SSD as a destination storage location for the first write command. In one embodiment, the FTL table is used to determine the location of first LUN pointed in response to the first write command.

After erasing all blocks within the first LUN at block 1106, the first content from the host, at block 1108, is written or programmed to first LUN in accordance with first write command. In one aspect, after generating the first write command by the host for NVM storage access, the first write command is sent to the SSD via a PCIe bus. In one embodiment, the process of erasing all blocks within the first LUN also includes moving the valid pages in the first LUN to a second LUN during a process of garbage collection for recycling valid sectors on an old block on that first LUN.

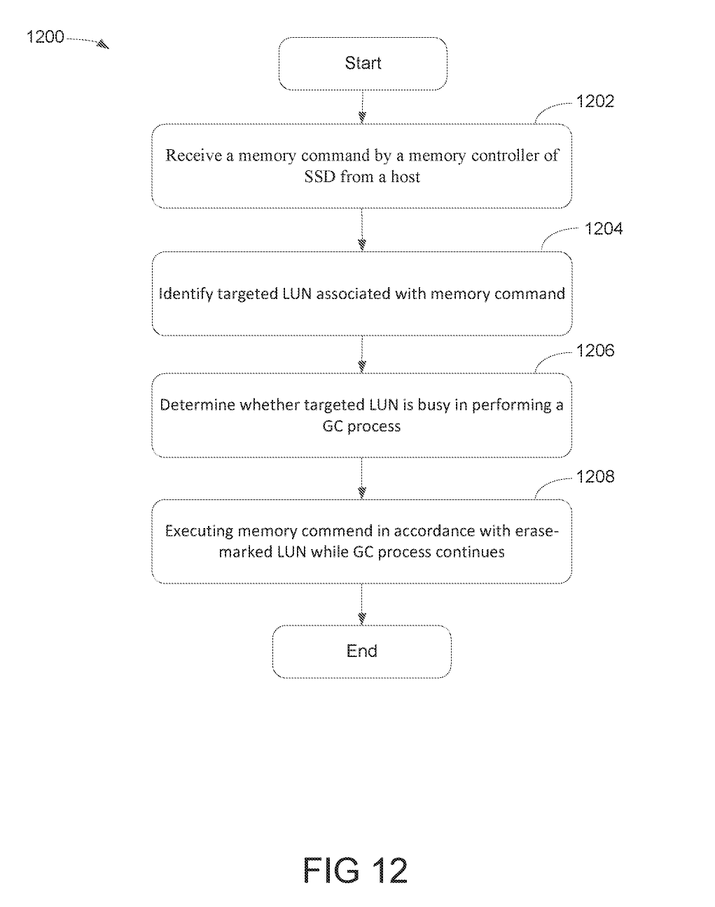

FIG. 12 is a flowchart 1200 illustrating a process of providing low latency memory access using an AEL approach in accordance with one embodiment of the present invention. At block 1202, a process for memory access to a NVM SSD via AEL receives a memory command by a memory controller of SSD from a host for an SSD memory access. In one aspect, the memory command can be a read command or a write command from a coupled or connected system.

At block 1204, the targeted LUN associated with the memory command is identified in response to the facilitation of FTL. For example, the targeted LUN is the location of data for the read operation. Alternatively, the targeted LUN is the location to storing write content for the write operation.

At block 1206, the process is capable of determining whether the targeted LUN is busy in performing one or more tasks such as a GC process of copying valid pages from an erase-marked LUN to the targeted LUN. It should be noted that the GC process takes long time to finish in comparison with a read operation.

At block 1208, the memory commend is executed in accordance with the erase-marked LUN while the GC process moving valid pages to the targeted LUN continues. For example, a read command can read the content from valid pages in the erase-marked LUN instead of targeted LUN whereby waiting for completion of GC is no longer necessary since the read can be accomplished via accessing the erase-marked LUN. In one example, the command is sent from the host to the SSD via a Peripheral Component Interconnect Express (“PCIe”) bus.

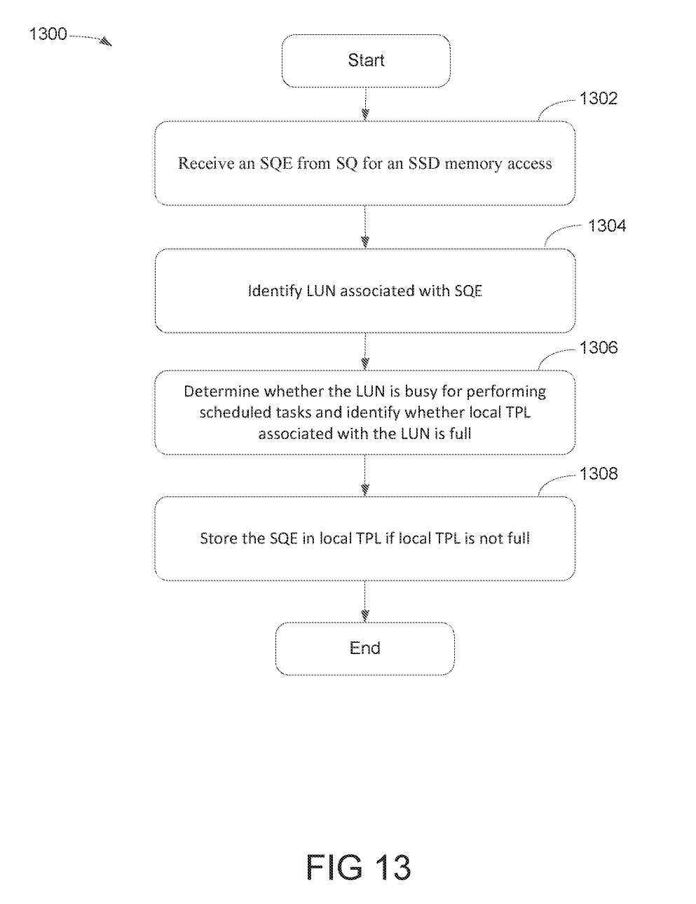

FIG. 13 is a flowchart 1300 illustrating a process of providing low latency memory access using STP approach in accordance with one embodiment of the present invention. At 1302, a process for memory access to an NVM SSD via a temporarily parking process receives a first SQE from a first SQ for a first SSD memory access by a host to an SSD.

At block 1304, the first LUN associated with the first SQE is identified in accordance with the facilitation of FTL table and/or CPU firmware.

At block 1306, the process is capable of determining whether the first LUN is busy for performing scheduled tasks. If the first LUN is busy, the process checks or determines whether a first local TPL associated with the first LUN is full.

At block 1308, the first SQE is stored in the first local TPL if the first local TPL is not full. Alternatively, the first SQE is stored in a global TPL if the first local TPL is full. In one embodiment, after obtaining a second SQE from a second SQ for a second SSD memory access by the host, the second LUN associated with the second SQE memory is identified in accordance with the facilitation of the FTL. Upon determining whether the second LUN is busy for performing scheduled tasks and identifying whether a second LPL associated with the second LUN is full if the second LUN is busy, the second SQE is stored in the second local TPL if the second local TPL is not full. Alternatively, the second SQE is stored in the global TPL if the second local TPL is full. The process is also capable of moving the second SQE from the global TPL to the second local TPL when the second local TPL becomes open or not full.

While particular embodiments of the present invention have been shown and described, it will be obvious to those of ordinary skills in the art that based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. A method for memory access to a non-volatile memory (“NVM”) solid state drive (“SSD”) via a memory controller snooping, comprising:
generating a first submission queue entry (“SQE”) for a first SSD memory access by a host to a connected SSD;
pushing the first SQE from the host to a submission queue (“SQ”) viewable by a controller of the SSD;
incrementing counter value of an SQ header pointer to reflect storage of the first SQE in the SQ;
detecting the first SQE in the SQ by a snooping component in the memory controller in accordance with the SQ header pointer; and
fetching the first SQE from the snooping component in the controller and executing one or more SSD memory instructions in response to content of the first SQE.

2. The method of claim 1, wherein detecting the first SQE in the SQ further includes identifying a difference between the SQ header pointer and an SQ tail pointer.

3. The method of claim 2, wherein pushing the first SQE from the host to a submission queue (“SQ”) includes storing the first SQE into the SQ via a Peripheral Component Interconnect Express (“PCIe”) bus connected between the host and the SSD.

4. The method of claim 3, further comprising:
generating a second SQE for a second SSD memory access by the host;
pushing the second SQE from the host to the SQ; and
incrementing counter value of the SQ header pointer to reflect storage of the second SQE in the SQ.

5. The method of claim 1, further comprising:
performing the first SSD memory access by the memory controller in accordance with the first SQE;
generating a first completion queue entry (“CQE”) in accordance with a first result of performance of the first SSD memory access; and
storing the first CQE by the memory controller to a completion queue (“CQ”) viewable by the host.

6. A method for memory access to a non-volatile memory (“NVM”) solid state drive (“SSD”) via a host CPU polling, comprising:
performing a first SSD memory access by a controller of SSD in accordance with a first submission queue entry (“SQE”) generated by a connected host;
generating a first completion queue entry (“CQE”) in accordance with a first result of performance of the first SSD memory access;
storing the first CQE by the controller to a completion queue (“CQ”) viewable by the host;
periodically polling the CQ by the host to identify whether the first CQE is present in response to the first SEQ;
fetching the first CQE from the CQ upon detection of the first CQE by the host via a polling activity; and
obtaining by the host the first result of the performance based on the first CQE.

7. The method of claim 6, further comprising:
generating a first submission queue entry (“SQE”) for a first SSD memory access by a host to a connected SSD; and
pushing the first SQE from the host to a submission queue (“SQ”) viewable by the controller.

8. The method of claim 7, further comprising:
incrementing counter value of an SQ header pointer to reflect storage of the first SQE in the SQ; and
detecting the first SQE in the SQ by a snooping component in the memory controller in accordance with the SQ header pointer.

9. The method of claim 8, further comprising fetching the first SQE from the SQ by the controller and executing one or more SSD memory instructions based on content of the first SQE.

10. The method of claim 6, further comprising:
performing a second SSD memory access by a memory controller in accordance with a second SQE;
generating a second completion queue entry (“CQE”) in accordance with a second result of performance of the second SSD memory access; and
storing the second CQE by the memory controller to the CQ.

11. A method for memory access to a non-volatile memory (“NVM”) solid state drive (“SSD”) via a cache content access, comprising:
receiving a first write command by a memory controller of SSD from a host for an SSD memory access;
confining writing process associated with the first write command to one (1) logic unit number (“LUN”) in an SSD at a given time for performing the first write command;
writing first content from the host to the LUN in accordance with the first write command;
caching the first content associated with the first write command to a cache while the first content is copied to the LUN; and
allowing the host to access the first content via the cache while the LUN is programmed for storing the first content. storing valid data during a process of garbage collection.

12. The method of claim 11, further comprising generating the first write command by the host for NVM storage access.

13. The method of claim 12, further comprising sending the first write command to the SSD via a Peripheral Component Interconnect Express (“PCIe”) bus.

14. The method of claim 11, wherein caching the first content associated with the first write command includes storing the first content in a snooping command cache located in a SSD controller.

15. The method of claim 11, wherein caching the first data content associated with the first write command includes storing the first content in a memory cache located in the controller.

16. A method for memory access to a non-volatile memory (“NVM”) solid state drive (“SSD”) via an LUN block erasing process, comprising:
receiving a first write command by a memory controller from a host for an SSD memory access;
identifying a first logic unit number (“LUN”) in an SSD as a destination storage location for the first write command;
erasing all blocks within the first LUN; and
programming first content from the host to the first LUN in accordance with the first write command.

17. The method of claim 16, further comprising generating the first write command by the host for NVM storage access.

18. The method of claim 17, further comprising sending the first write command to the SSD via a Peripheral Component Interconnect Express (“PCIe”) bus.

19. The method of claim 16, wherein identifying a first logic unit number (“LUN”) in an SSD further includes determining the first LUN pointed by flash translation layer (“FTL”) table in response to the first write command.

20. The method of claim 16, wherein erasing all blocks within the first LUN includes moving valid pages in the first LUN to a second LUN during a process of garbage collection for recycling valid sectors on an old block in first LUN.

21. A method for memory access to a non-volatile memory (“NVM”) solid state drive (“SSD”) via accessing erase-marked logic unit number (“LUN”), comprising:
receiving a memory command by a memory controller of SSD from a host for an SSD memory access;
identifying targeted LUN associated with the memory command in response to facilitation of a flash translation table (“FTL”);
determining whether the targeted LUN is busy in performing a garbage collection (“GC”) process with copying a set of valid pages from an erase-marked LUN to the targeted LUN; and
executing the memory commend in accordance with the erase-marked LUN while the GC process to the targeted LUN continues.

22. The method of claim 21, wherein receiving a memory command by a memory controller of SSD includes receiving one of a read command and a write command from a coupled system.

23. The method of claim 21, further comprising sending the command to the SSD via a Peripheral Component Interconnect Express (“PCIe”) bus.

24. A method for memory access to a non-volatile memory (“NVM”) solid state drive (“SSD”) via a temporarily parking process, comprising:
receiving a first submission queue entry (“SQE”) from a first submission queue (“SQ”) for a first SSD memory access by a host to an SSD;
identifying first LUN associated with the first SQE in accordance with facilitation of a flash translation table (“FTL”);
determining whether the first LUN is busy for performing scheduled tasks and identifying whether a first local temporarily parking lot (“TPL”) associated with the first LUN is full if the first LUN is busy; and
storing the first SQE in the first local TPL if the first local TPL is not full.

25. The method of claim 24, further comprising storing the first SQE in a global TPL if the first local TPL is full.

26. The method of claim 25, further comprising:
obtaining a second SQE from a second SQ for a second SSD memory access by the host; and
identifying second LUN associated with the second SQE memory in accordance with facilitation of the FTL.

27. The method of claim 26, further comprising:
determining whether the second LUN is busy for performing scheduled tasks and identifying whether a second LPL associated with the second LUN is full if the second LUN is busy; and
storing the second SQE in the second local TPL if the second local TPL is not full.

28. The method of claim 27, further comprising storing the second SQE in the global TPL if the second local TPL is full.

29. The method of claim 28, further comprising moving the second SQE from the global TPL to the second local TPL when the second local TPL becomes open.
